(19) United States
(12) Patent Application Publication
(10) Pub. No.: US 2004/0245984 A1
(43) Pub. Date: Dec. 9, 2004

(54) Apparatus and method for characterizing impedance presented to a write driver in a write head assembly

(76) Inventors: Nathen Barton, Dallas, TX (US); Bryan E. Bloodworth, Irving, TX (US); Taras Dudar, Dallas, TX (US); James Nodar, Dallas, TX (US)

Correspondence Address: TEXAS INSTRUMENTS INCORPORATED, P O BOX 655474, M/S 3999, DALLAS, TX, 75265

(21) Appl. No.: 10/454,008

(22) Filed: Jun. 3, 2003

(51) Int. Cl. G01R 33/12

(52) U.S. Cl. 324/210

(57) ABSTRACT

An apparatus for characterizing impedance presented to a write driver device in a write head assembly for use with an electromagnetic storage product includes: (a) a test impedance unit coupled with the write driver device; and (b) a measuring unit coupled with the test impedance unit. The measuring unit receives a measured parameter associated with the test impedance unit and compares the measured parameter with a reference parameter. The measuring unit indicates a result of the comparing.

### BACKGROUND OF THE INVENTION

The present invention is directed to electromagnetic storage products, and especially to electromagnetic storage products using a spinning media, such as a hard disk drive. In particular the present invention is directed to a write driver device in a write head assembly for use with an electromagnetic storage product. Write head assemblies are commonly embodied in a head stack assembly. Preamplifier devices or chips may be mounted upon a head stack assembly or mounted elsewhere in a product and electrically coupled with a head stack assembly.

In electromagnetic storage products using spinning media, such as hard disk drive (HDD) products, write heads are connected to a preamplifier chip in a write head assembly through external wiring. During the manufacturing process or during normal operation, the wiring connected to the write head may become shorted together, thereby present a low impedance return path for write head current to return from the write head to the preamplifier chip. Such a shorted configuration renders the write head assembly inoperable and is an occasion for repairing or replacing the write head assembly.

This shorted condition is commonly tested for late in the course of manufacturing write head assemblies. Testing is commonly carried out using a substantially completely assembled storage product including a write head assembly and a disk by writing a sequence of data to the disk, then reading back the stored sequence. Analysis of the data read from the disk can subsequently lead to the conclusion that there is an error in the write path. When such an error is detected, the write head assembly (also referred to as a head stack assembly—HSA), usually must be rebuilt or discarded. This existing prior art testing method is expensive because all labor and material assembly costs up to the point in time that a fault is discovered are lost because of the failure of a particular subassembly (i.e., the write head assembly) in the storage product.

There is a need for an apparatus and method for characterizing impedance presented to a write driver device in a write head assembly that can be employed before assembly of a storage product is substantially complete. Such characterizing may include, by ay of example and not by way of limitation, applying a pass-fail test criteria to determine whether the impedance is acceptable or determining a value for the impedance. Once a known value is determined for the impedance one may use that known value to aid in establishing write head operational characteristics, such as write current, write current overshoot and other operational parameters.

### SUMMARY OF THE INVENTION

An apparatus for characterizing impedance presented to a write driver device in a write head assembly for use with an electromagnetic storage product includes: (a) a test impedance unit coupled with the write driver device; and (b) a measuring unit coupled with the test impedance unit. The measuring unit receives a measured parameter associated with the test impedance unit and compares the measured parameter with a reference parameter. The measuring unit indicates a result of the comparing.

A method for characterizing impedance presented to a write driver device in a write head assembly for use with an electromagnetic storage product includes the steps of: (a) providing a test impedance unit coupled with the write driver device; (b) measuring a parameter associated with the test impedance unit; (c) comparing the parameter with a reference parameter; and (d) indicating a result of the comparing.

It is, therefore, an object of the present invention to provide an apparatus and method for characterizing impedance presented to a write driver device in a write head assembly that can be employed before assembly of a storage product is substantially complete.

Further objects and features of the present invention will be apparent from the following specification and claims when considered in connection with the accompanying drawings, in which like elements are labeled using like reference numerals in the various figures, illustrating the preferred embodiments of the invention.

### BRIEF DESCRIPTION OF THE DRAWINGS

FIG. 1 is a simplified perspective view of a write head assembly in an operational relation with a storage disk.

FIG. 2 is a simplified schematic plan view of a write head assembly illustrating physical locations of elements of the assembly.

FIG. 3 is a simplified schematic view of a write head assembly illustrating electrical relations in the assembly.

FIG. 4 is a simplified schematic diagram illustrating various impedances presented to a write driver device in a write head assembly.

FIG. 5 is a simplified schematic diagram illustrating the preferred embodiment of the apparatus of the present invention.

FIG. 6 is a flow chart illustrating the method of the present invention.

FIG. 7 is a flow chart illustrating a method of using the present invention to precisely ascertain write head impedance of a write head assembly.

### DETAILED DESCRIPTION OF THE PREFERRED EMBODIMENT

Hard disk drives (HDD) are electromagnetic storage products that store information by manipulating the magnetic properties of a spinning media often known as a disk. Hard disk drives commonly include thin film write heads that are held close to the disk's surface by suspension from a head stack assembly. The write heads suspended adjacent to the disk are coupled with a preamplifier or other driver circuit via wires that are supported on the head stack assembly between the driver circuit and the write heads. The driver circuit often is embodied in or includes a preamplifier device and contains electronic circuitry to drive the write heads (also called the write elements) to store information to the disk by changing the current direction within the write head.

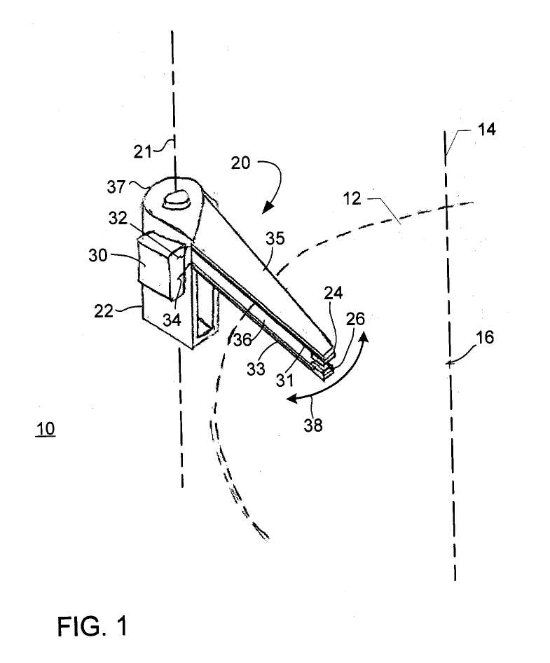

FIG. 1 is a simplified perspective view of a write head assembly in an operational relation with a storage disk. In FIG. 1, an electromagnetic storage product 10 includes a magnetic disk 12 that is perpendicularly symmetrical about an axis 14 and spins about a center 16 located on axis 14. Storage product 10 further includes a write head assembly or head stack assembly 20. Disk 12 is illustrated in phantom to facilitate clearer illustration of head stack assembly 20. Head stack assembly 20 includes a head stack chassis 22 supporting write heads 24, 26 on opposing sides of disk 12. Head stack chassis 22 includes arms 35, 36 supporting write heads 24, 26 adjacent to disk 12 and a base portion 37. Arms 35, 36 are fixedly connected with base portion 37, or may be integrally formed with base portion 37. Driver circuitry 30 is also mounted to head stack chassis 22 at base member 37 at a locus distal from write heads 24, 26. Electrical wires or cables 32, 34 couple driver circuitry 30 with write heads 24, 26. In a preferred embodiment, cables 32, 34 are situated in grooves along edges 31, 33 of arms 35, 36 and additional cables situated in grooves along edges opposing edges 31, 33 (not shown in detail in FIG. 1) couple driver circuitry 30 with write heads 24, 26. Head stack assembly 20 preferable rotates about an axis 21, as indicated by arrow 38, to position write heads 24, 26 appropriately with respect to disk 12 for reading data at a selected data site on disk 12 (not shown in detail in FIG. 1). Preferably, axes 14, 21 are substantially parallel.

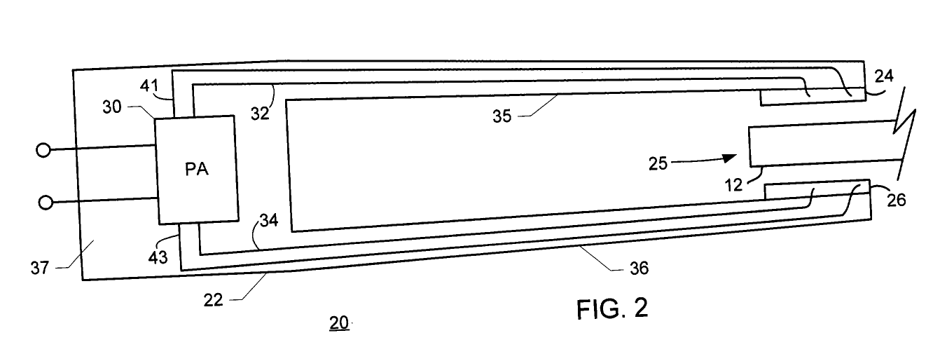

FIG. 2 is a simplified schematic plan view of a write head assembly illustrating physical locations of elements of the assembly. In FIG. 2, write head assembly, or head stack assembly 20 includes head stack chassis 22 supporting write heads 24, 26 for orientation about a disk 12 that may be deployed for rotation within gap 25 between arms 35, 36. Arms 35, 36 are fixedly connected with base portion 37, or may be integrally formed with base portion 37. Driver circuitry 30 (embodied in or including a preamplifier device) may be mounted to head stack chassis 22 at base member 37 at a locus distal from write heads 24, 26. Electrical wires or cables 32, 34, 41, 43 couple driver circuitry 30 with write heads 24, 26.

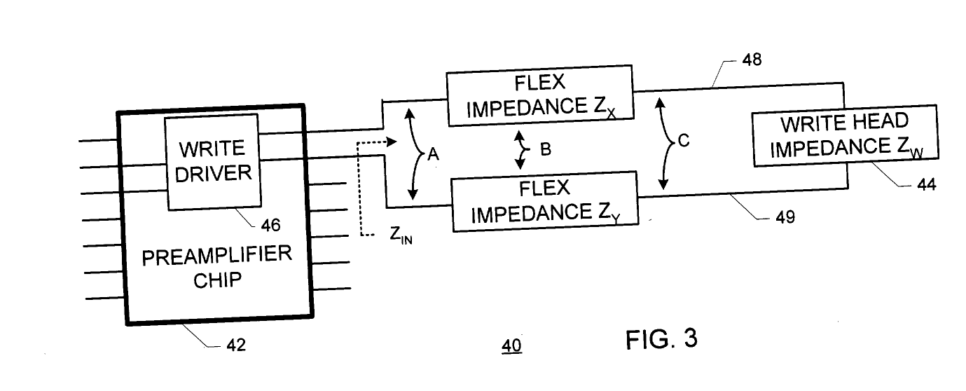

FIG. 3 is a simplified schematic view of a write head assembly illustrating electrical relations in the assembly. In FIG. 3, a write head assembly, or head stack assembly 40 includes a preamplifier chip 42 and a write head unit 44. Preamplifier chip 42 includes a write driver device 46. Write head unit 44 is an embodiment representing impedance of write heads 24, 26 (FIGS. 1 and 2). Preamplifier chip 42 is coupled with write head unit 44 via wires 48, 49. Specifically, wires 48, 49 are coupled with write driver device 46. Impedance seen by write driver device 46 is represented by arrow Z_{IN}. Write driver device 46 sees an impedance Z_{W} presented by write head unit 44. Connecting wire 48 presents an impedance Z_{X} to write driver device 46. Connecting wire 49 presents an impedance Z_{Y} to write driver device 46.

Because of errors during manufacturing of write head assembly 40 or even during normal operation of write head assembly 40, shorts in connecting wires 48, 49 may develop at one or more of loci “A”, “B” or “C”. One (or more) such shorts in connecting wires 48, 49 allow write head current to flow though a lower impedance path instead of through write head unit 44. In such a situation write head unit 44 is unable to properly manipulate the magnetic properties of the disk situated in gap 25 (FIG. 2) and the write function of write head assembly 40 fails. The electromagnetic storage system employing write head assembly 40 is inoperable unless the short condition is corrected. Correction may involve reworking or replacing write head assembly 40 or, more commonly, replacing the entire electromagnetic storage unit that includes write head assembly 40.

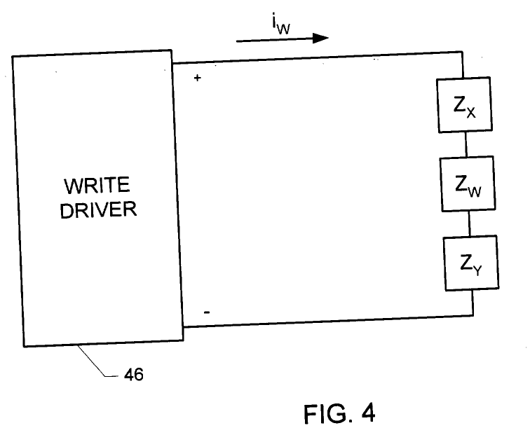

FIG. 4 is a simplified schematic diagram illustrating various impedances presented to a write driver device in a write head assembly. FIG. 4 is a simplified representation of the impedances illustrated in FIG. 3. In FIG. 4, write driver device 46 generates a write current i_{W} and sees impedances Z_{X}, Z_{W}, Z_{Y}.

In FIG. 4, when no errors are present, impedance seen by write driver device 46 is

Z_{TOTAL}=Z_{X}+Z_{W}+Z_{Y} [1]

Historically, manufacturers of electromagnetic storage devices such as hard disk drive manufacturers have not been able to test write head assemblies for shorts across write heads (e.g., as discussed in connection with FIG. 3) until late in the manufacturing process, usually after the write head assembly is incorporated with a disk in a storage product. Testing for shorts in those circumstances involved writing a sequence of data to the disk and then reading back the sequence that was written. Analysis of the data that was read back was evaluated to ascertain whether unacceptable errors occurred. If unacceptable errors occurred, it was concluded that there was an error in the write path for some reason. If such an error was detected, the head stack assembly (e.g., head stack assembly 20; FIG. 1) was replaced or reworked. Sometimes the entire drive circuit or even the entire electromagnetic storage device including a disk and the damaged drive was scrapped. Such testing late in the manufacturing process, after significant labor and materials costs are invested in the device being manufactured, is expensive. Correction of problems discovered by such late testing is expensive and disruptive. Moreover, manufacturers of electromagnetic storage devices such as hard disk drive manufacturers have not been able to easily optimize the write process for a given product. It would be useful for a manufacturer to be able to precisely measure the impedance of the write head so that the write process may be adjusted for optimum performance, particularly by adjustment of direct current (DC) write current and current overshoot. Knowing the impedance of a write head and adjusting a write process to optimize performance of a product that includes that write head permits effectively minimizing product-to-product impedance variations and increasing optimum performance.

A solution to detecting a low impedance condition that indicates a short across a write head unit (e.g., write head unit 44; FIG. 3) is to introduce a short across the write head circuit (preferably across impedances Z_{X}, Z_{W}, Z_{Y}) in a manner that can be integrated into and preferably controlled by write driver device 46. A circuit controlledly implementing such a short circuit path can be used after assembly of a head stack assembly to detect whether the write head unit (e.g., write head unit 44; FIG. 3) is properly assembled and presents the proper impedance. Such testing can be carried out before the head stack assembly is installed in a storage product so that testing need not be delayed until more labor and materials are included in the tested unit. If an error is detected in the head stack assembly, then the errant assembly may be rebuilt or scrapped, rather than having to disassemble a storage product to effect repairs or having to discard an entire storage product.

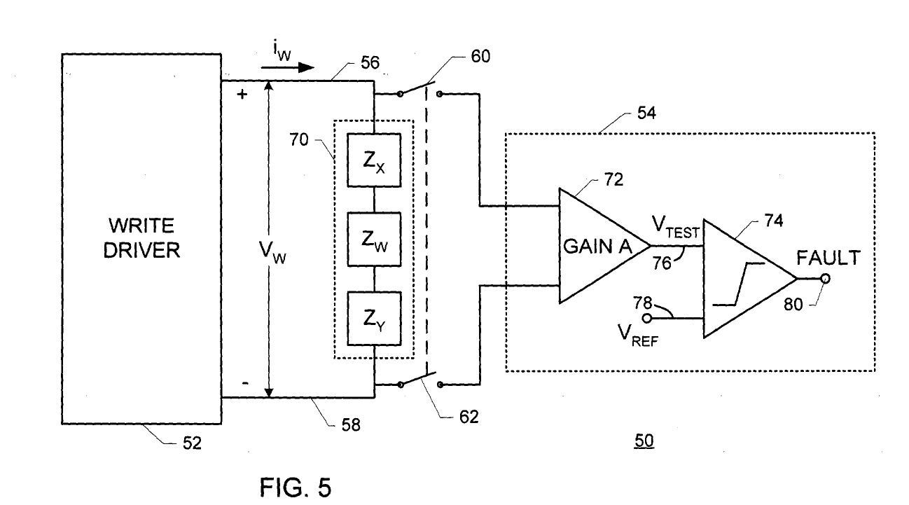

FIG. 5 is a simplified schematic diagram illustrating the preferred embodiment of the apparatus of the present invention. In FIG. 5, a write head assembly 50 includes a write driver device 52 and a test apparatus 54. A write head unit (not shown in detail in FIG. 5) presents a write head impedance Z_{W} to write driver device 52 when coupled with write driver device 52. Wires 56, 58 coupling write head impedance Z_{W} with write driver device 52 present impedances Z_{X}, Z_{Y} to write driver device 52 when coupled with write driver device 52. Switches 60, 62 cooperate to connect test apparatus 54 across a test impedance 70 comprising impedances Z_{X}, Z_{Y}, Z_{W} when testing is to be performed. Test apparatus 54 includes an amplifier unit 72 and a fault monitor unit 74. Test impedance unit 70 presents a test impedance Z_{TEST} to write driver device 52 when test apparatus 54 is coupled across test impedance 70 via switches 60, 62.

When switches 60, 62 are in an open position, write head impedance Z_{W} is connected with write driver device 52 in an operational configuration (also including wire impedances Z_{X}, Z_{Y} contributed by wires 56, 58). If no errors are present in the loop including write driver device 52, wires 56, 58 and write head impedance Z_{W} the impedance seen by write driver device 52 is given by expression [1].

Z_{TOTAL}=Z_{X}+Z_{W}+Z_{Y} [1]

If a bias current i_{W} is passed through wires 56, 58 and write head impedance Z_{W}, a voltage V_{W} is developed across write driver device 52:

V_{W}=i_{W}(Z_{X}+Z_{W}+Z_{Y}) [2]

If a short develops such that current no longer flows through write head impedance Z_{W}, then an impedance Z_{SHORT} is seen by write driver device 52 that will be less than Z_{TOTAL} (expression [1]), and a voltage V_{W1} is developed across write driver device 52 that is less than voltage V_{W}.

Thus:

Z_{SHORT}<Z_{TOTAL}<Z_{X}+Z_{W}+Z_{Y} [3]

and

V_{W1}<V_{W} [4]

Various operating parameters and characteristics are known in hard drive memory devices, such as flex resistance (Z_{X}, Z_{Y}) of wires 56, 58 and write head resistance Z_{W}. Knowing such characteristics and parameters, to determine whether a short has developed across the write head (e.g., write head unit 44; FIG. 3) the measured impedance seen by write driver device 52 can be compared to a predetermined reference value based upon known impedances Z_{X}, Z_{Y}, Z_{W}. If the measured value is less than the reference value, switches 60, 62 may be established in a closed position to connect test apparatus 54 across test impedance 70 and current i_{W} is passed through test impedance unit 70. Voltage across test impedance unit 70 is buffered and amplified by amplifier unit 72 and a resulting voltage V_{TEST} is provided at a first input 76 to fault monitor unit 74. Fault monitor unit 74 receives a reference voltage V_{REF} at a second input 78. Reference voltage V_{REF} is preferably selected so that a fault condition may be reported at a fault indicating output locus 80 according to the comparison

V_{TEST}>V_{REF} [symbol] Normal Conditions/No Fault [5]

V_{TEST}<V_{REF} [symbol] Fault/Short Across Write Head [6]

The relationship between V_{TEST} and Z_{TEST} is:

V_{TEST}=Z_{TEST}*i_{W}*A [7]

Where A=gain of amplifier unit 72 If test impedance 70 is a value Z_{TEST} that is less than a predetermined fault impedance Z_{FAULT} at which a write head unit will not operate properly, where

$${Z}_{FAULT} = \frac{{V}_{REF}}{Aiw} \qquad [ 8 ]$$

where A is the gain of amplifier unit 72

Then test apparatus 54 reports a fault. For proper operation of test apparatus 54, fault impedance Z_{FAULT} is preferably chosen such that,

Z_{X}+Z_{Y}<Z_{FAULT}<Z_{X}+Z_{W}+Z_{Y} [9]

Thus, when impedance seen by write driver device 52 is less than a predetermined value, switches 60, 62 are closed to connect test apparatus 54 across test impedance 70. Test apparatus 54 provides a test voltage V_{TEST} (derived from voltage across test impedance 70) to fault monitor unit 74. Fault monitor unit 74 compares test voltage V_{TEST} with a reference voltage V_{REF} and indicates presence of a fault when predetermined relationship is extant between test voltage V_{TEST} and reference voltage V_{REF}.

Switches 60, 62 may be eliminated so that test apparatus 54 is permanently coupled across test impedance 70. In such a configuration an enable signal may be provided to amplifier unit 72 (not shown in FIG. 5) to effect turning amplifier unit 72 on or off. When amplifier unit 72 is enabled, or is turned on, test apparatus 54 is effectively coupled across test impedance 70. When amplifier unit 72 is not enabled, or is turned off, test apparatus 54 is effectively electrically isolated from test impedance 70.

Test apparatus 54 may be employed to precisely ascertain impedance Z_{W} rather than simply discern a “Pass/Fail” condition vis-à-vis a fault criterion. If one provides a variable reference voltage V_{REF}, then reference voltage V_{REF} may be varied until V_{REF}=V_{TEST} (i.e., the onset of a fault condition). Ascertaining the value of reference voltage V_{REF} at which a fault condition first occurs (i.e., the onset of a fault condition) and knowing current i_{W}, one can precisely ascertain impedance Z_{W} and the impedance of a write head unit is thus precisely determined. Precisely determining impedance Z_{W} permits manufacturers of electromagnetic storage devices such as hard disk drive manufacturers to optimize the write process for a given product optimum performance, particularly by adjustment of direct current (DC) write current and current overshoot. Knowing the impedance of a write head and adjusting the write process to optimize performance of a product that includes that write head permits effectively minimizing product-to-product impedance variations.

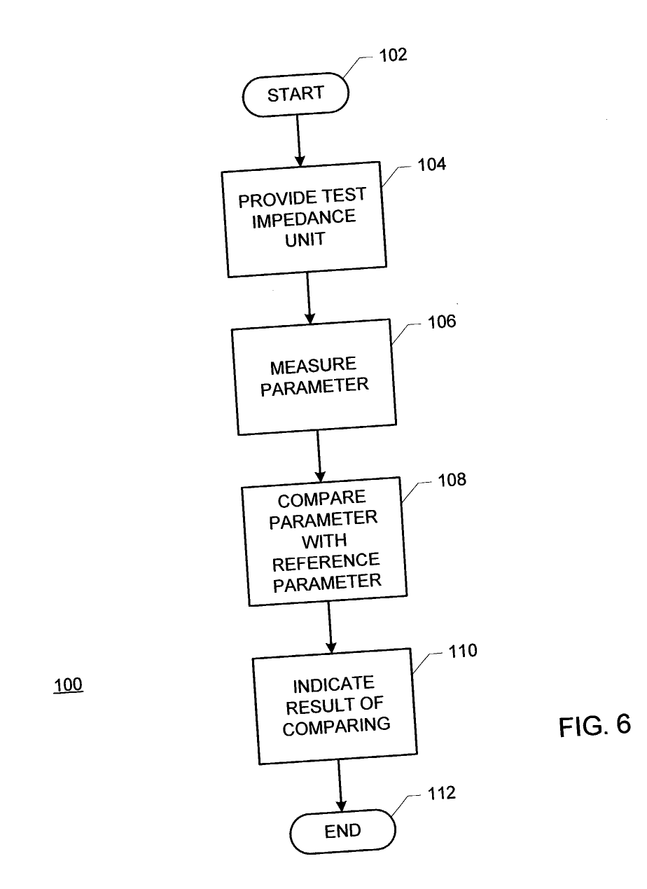

FIG. 6 is a flow chart illustrating the method of the present invention. In FIG. 6, a method 100 for ascertaining impedance presented to a write driver device in a write head assembly for use with an electromagnetic storage product begins at a START locus 102. Method 100 continues with the step of providing a test impedance unit coupled with the write driver device, as indicated by a block 104. Method 100 continues by measuring a parameter associated with the test impedance unit, as indicated by a block 106. Method 100 continues by comparing the parameter with a reference parameter, as indicated by a block 108. Method 100 continues with the step of indicating a result of the comparing, as indicated by a block 110. Method 100 terminated at an END locus 112.

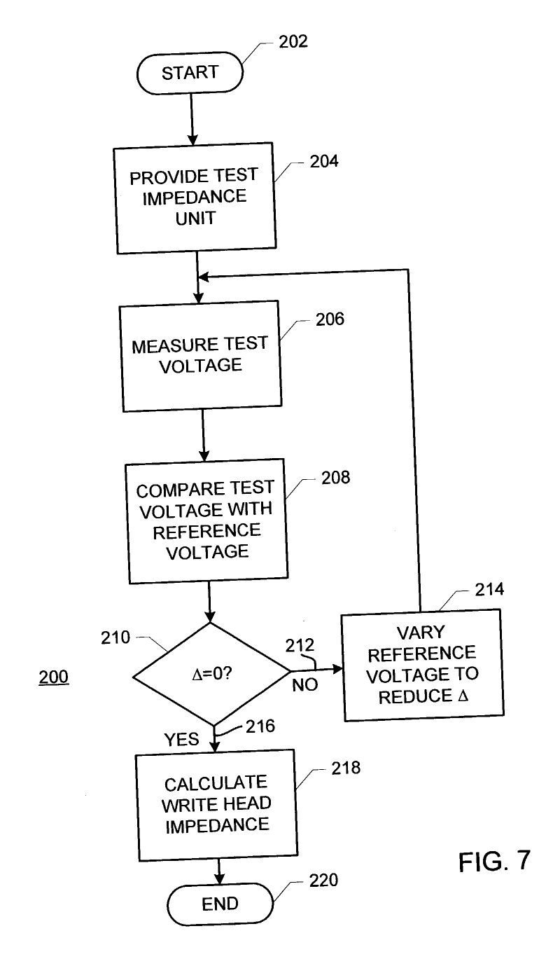

FIG. 7 is a flow chart illustrating a method of using the present invention to precisely ascertain write head impedance of a write head assembly. In FIG. 7, a method 200 for ascertaining write head impedance using test apparatus 54 (FIG. 5) begins at a START locus 202. Method 200 continues with the step of providing a test impedance unit, such as test unit 54 (FIG. 5), as indicated by a block 204. Method 200 continues with the step of measuring a test voltage, such as voltage V_{W} (FIG. 5), as indicated by a block 206. Method 200 continues with the step of comparing test voltage V_{W} with a reference voltage, such as reference voltage V_{REF} (FIG. 5), as indicated by a block 208. Method 200 then poses a query whether the difference between test voltage V_{W} and reference voltage V_{REF} is equal to zero, as indicated by a query block 210. If the difference between test voltage V_{W} and reference voltage V_{REF} is not equal to zero, method 200 proceeds according to NO response line 212 and reference voltage V_{REF} is varied to reduce the difference (i.e., the Δ) between test voltage V_{W} and reference voltage V_{REF}, as indicated by a block 214. Method 200 returns to measure test voltage V_{W} again according to block 206, and proceeds thereafter as previously described to perform steps represented by blocks 206, 208, 210. If the difference between test voltage V_{W} and reference voltage V_{REF} is equal to zero, method 200 proceeds according to YES response line 216 and write head impedance Z_{W} (FIG. 5) is calculated, as indicated by a block 218. Method 200 terminates at an END locus 220.

It is to be understood that, while the detailed drawings and specific examples given describe preferred embodiments of the invention, they are for the purpose of illustration only, that the apparatus and method of the invention are not limited to the precise details and conditions disclosed and that various changes may be made therein without departing from the spirit of the invention which is defined by the following claims:

I claim:

1. An apparatus for characterizing impedance presented to a write driver device in a write head assembly for use with an electromagnetic storage product; the apparatus comprising:
(a) a test impedance unit coupled with said write driver device; and
(b) a measuring unit coupled with said test impedance unit;
said measuring unit receiving a measured parameter associated with said test impedance unit and comparing said measured parameter with a reference parameter; said measuring unit indicating a result of said comparing.

2. An apparatus for characterizing impedance presented to a write driver device in a write head assembly for use with an electromagnetic storage product as recited in claim 1 wherein the apparatus is integrally included within said write driver device.

3. An apparatus for characterizing impedance presented to a write driver device in a write head assembly for use with an electromagnetic storage product as recited in claim 1 wherein said reference parameter is variable.

4. An apparatus for characterizing impedance presented to a write driver device in a write head assembly for use with an electromagnetic storage product as recited in claim 2 wherein said reference parameter is variable.

5. An apparatus for characterizing impedance loading a write driver in a head stack assembly for use with an electromagnetic storage product; the apparatus comprising:
(a) a test impedance unit coupled with said write driver device; and
(b) a measuring unit coupled with said test impedance unit;
said measuring unit receiving a measured parameter associated with said test impedance unit and comparing said measured parameter with a reference parameter; said measuring unit indicating a result of said comparing.

6. An apparatus for characterizing impedance loading a write driver in a head stack assembly for use with an electromagnetic storage product as recited in claim 5 wherein the apparatus is integrally included within said write driver device.

7. An apparatus for characterizing impedance loading a write driver in a head stack assembly for use with an electromagnetic storage product as recited in claim 5 wherein said reference parameter is variable.

8. An apparatus for characterizing impedance loading a write driver in a head stack assembly for use with an electromagnetic storage product as recited in claim 6 wherein said reference parameter is variable.

9. A method for characterizing impedance presented to a write driver device in a write head assembly for use with an electromagnetic storage product; the method comprising the steps of:
(a) providing a test impedance unit coupled with said write driver device;
(b) measuring a parameter associated with said test impedance unit;
(c) comparing said parameter with a reference parameter; and
(d) indicating a result of said comparing.

10. A method for characterizing impedance presented to a write driver device in a write head assembly for use with an electromagnetic storage product as recited in claim 9 wherein said indicating a result of said comparing comprises the further steps of:
(1) establishing a pass-fail criteria for determining a pass result and a fail result for said comparing step;
(2) determining whether said result indicates said pass result or said fail result; and
(3) effecting said indicating to relate one of said pass result and said fail result.

11. A method for characterizing impedance presented to a write driver device in a write head assembly for use with an electromagnetic storage product as recited in claim 9 wherein said test impedance unit is integrally included within said write driver device.

12. A method for characterizing impedance presented to a write driver device in a write head assembly for use with an electromagnetic storage product as recited in claim 9 wherein said reference parameter is variable.

13. A method for characterizing impedance presented to a write driver device in a write head assembly for use with an electromagnetic storage product as recited in claim 11 wherein said reference parameter is variable.

14. A method for characterizing impedance presented to a write driver device in a write head assembly for use with an electromagnetic storage product as recited in claim 12 wherein said comparing step includes the further steps of:
(1) determining whether a difference between said parameter and said reference parameter is less than a predetermined value;
(2) if said difference is greater than said predetermined value, varying said reference parameter to reduce said difference and again performing said comparing step and said determining step; and
(3) when said difference is less than or equal to said predetermined value, using the then-extant value of said reference parameter in determining a characteristic of said write head assembly.

15. A method for characterizing impedance presented to a write driver device in a write head assembly for use with an electromagnetic storage product as recited in claim 11 wherein said indicating a result of said comparing comprises the further steps of:
(1) establishing a pass-fail criteria for determining a pass result and a fail result for said comparing step;
(2) determining whether said result indicates said pass result or said fail result; and
(3) effecting said indicating to relate one of said pass result and said fail result.

16. A method for characterizing impedance presented to a write driver device in a write head assembly for use with an electromagnetic storage product as recited in claim 12 wherein said reference parameter is variable.

17. A method for characterizing impedance presented to a write driver device in a write head assembly for use with an electromagnetic storage product as recited in claim 16 wherein said comparing step includes the further steps of:
(1) determining whether a difference between said parameter and said reference parameter is less than a predetermined value;
(2) if said difference is greater than said predetermined value, varying said reference parameter to reduce said difference and again performing said comparing step and said determining step; and
(3) when said difference is less than or equal to said predetermined value, using the then-extant value of said reference parameter in determining a characteristic of said write head assembly.
